(19) United States
(12) Patent Application Publication
(10) Pub. No.: US 2024/0077980 A1
(43) Pub. Date: Mar. 7, 2024

(54) TRANSPARENT CONDUCTIVE SUBSTRATE AND A DOUBLE-SIDE PHOTOLITHOGRAPHIC METHOD USING THE SAME

(71) Applicant: DUPONT ELECTRONICS, INC., WILMINGTON, DE (US)

(72) Inventor: YI-TING CHEN, HSINCHU (TW)

(21) Appl. No.: 18/454,300

(22) Filed: Aug. 23, 2023

Related U.S. Application Data
(60) Provisional application No. 63/401,878, filed on Aug. 29, 2022.

(51) Int. Cl. G06F 3/044; B32B 27/08; B32B 27/36; G03F 7/00; G03F 7/42

(52) U.S. Cl. CPC G06F 3/0446; B32B 27/08; B32B 27/36; G03F 7/0007; G03F 7/42; B32B 2250/03; B32B 2250/244; B32B 2255/10; B32B 2255/205; B32B 2307/412; B32B 2457/208; G06F 2203/04103

(57) ABSTRACT

The present invention provides a transparent conductive substrate, sequentially comprising: a first resist layer, a first transparent conductive layer, a transparent core, a second transparent conductive layer, and a second resist layer; wherein the first resist layer is composed of a UV-light sensitive composition (C1); and the second resist layer is composed of a visible-light sensitive composition (C2).

The present invention provides a double-side photolithographic method for manufacturing transparent conductive laminates. The transparent conductive laminates manufactured by the inventive method may be incorporated into touch panels.

### FIELD OF THE INVENTION

The present invention relates to transparent conductive substrates and double-side methods for simultaneously forming conductive patterns on both sides of the transparent conductive substrates.

### BACKGROUND OF THE INVENTION

Photosensitive compositions are well known to be used in the production of printed circuits, in the formation of photolithographic printed plates, and in proofing applications. Regardless the various applications, the main function of the photosensitive compositions is to form a resist pattern. One of the general processes in forming a resist pattern from a negative type photosensitive composition typically includes: i) applying a photosensitive composition onto a substrate, ii) imagewise exposing to active light rays, and iii) developing to form a resist pattern. After etching or plating to form a conductive pattern, the cured resist pattern is generally stripped from the processed substrate. To improve the production efficiency, two unique resist patterns may be simultaneously formed on each side of a non-transparent substrate by a double-side photolithographic method. The double-side photolithographic method includes forming a resist layer on each side of a substrate sequentially or simultaneously, followed by imagewise exposing, developing, etching or stripping, and stripping simultaneously.

Recently, touch panels (i.e., a display device attached with a touch sensor) have been widely applied to various electronic devices such as cellular phones, personal digital assistants (PDA), navigation devices, and the like. Known touch sensors may be categorized as a resistive type or a capacitance type. In particular, the capacitive touch sensor can receive multi-touches and is widely employed for uses such as portable devices. The basic technology of the capacitive touch sensor works off on an electrostatic field that is created by layers of conductive materials individually etched to form a x-y conductive grid.

For touch panel applications, the touch sensors require precise alignment of circuits with different patterns on both sides of a transparent core and the circuit patterns may be formed sequentially by photolithographic method. However, given the optically transparent nature of the substrate and certain transparent conductor materials such as indium-tin-oxide (ITO), the double-side photolithographic method is not applicable. Because the active light rays used to expose the resist on one side of the transparent core and/or transparent conductive layers will also unavoidably expose the photoresist on the opposite side of the transparent core. As a result, the same patterns will be inevitably formed on both surfaces of the transparent core. However, for the touch panel applications, it requires having different circuit patterns (i.e., the x-y conductive grid) on both sides of the transparent core.

H. Kobayashi in US20110151215 A1 discloses a method for manufacturing a transparent conductive laminate by employing a transparent core that contains a ultraviolet absorbing agent or applying an adhesive layer between two transparent cores which absorbs ultraviolet light. The drawbacks of the method include changing the transparency and thickness, and other properties such as mechanical strength, chemical resistance, and conductivity of the transparent conductive laminate made therefrom.

R. Petcavich et al also discloses a method for forming circuits on two sides of a transparent core in US20210318769 A1. The method for manufacturing a touch sensor comprises: applying a UV absorbing layer to one side of a transparent core; then applying a first photoresist layer on the UV absorbing layer on one side, and a second photoresist layer directly on the opposing side of the transparent core; photo-patterning both photoresist layers using UV radiation; and forming conductive circuits on two-sides of the transparent core. One apparent disadvantage of the method is by adding the UV absorbing layer (i.e., 10 to 15 microns), the touch sensors made therefrom will have an increased total thickness. Not to mention that these touch sensors may have the issue of reduction in visibility.

The present invention addresses the abovementioned problems by providing photosensitive compositions and dry films made therefrom that have excellent tunability on light sensitivity, and may be photocured by exposing to different light rays simultaneously. Consequently, the double-side photolithographic method becomes applicable for manufacturing a transparent conductive laminate without introducing extra layer or light blocking/absorbing material to the resulting laminate. Furthermore, the conductive substrate's transparency, mechanical strength, chemical resistance, and conductivity are kept with no change.

### SUMMARY OF THE INVENTION

A first aspect of the present invention is a transparent conductive substrate for manufacturing a transparent conductive laminate, sequentially comprising: a first resist layer, a first transparent conductive layer, a transparent core, a second transparent conductive layer, and a second resist layer;
wherein
   the transparent core has a total transmittance in the rage of 400 nm-800 nm (T₄₀₀₋₈₀₀) being 60% or more;
   the first resist layer is composed of a UV-light sensitive composition;
   the second resist layer is composed of a visible-light sensitive composition;
   the UV-light sensitive composition undergoes photopolymerization by exposing to light rays with a wavelength of below 400 nm; and
   the visible-light sensitive composition undergoes photopolymerization by exposing to light rays of a wavelength region of 400 nm to 800 nm.

A second aspect of the present invention is a method for manufacturing the present transparent conductive substrate, comprising:
(i) providing a transparent core;
(ii) forming a first transparent conductive layer on one surface of the transparent core;
(iii) forming a second transparent conductive layer on the opposite surface of the transparent core;
(iv) applying a UV-light sensitive composition (C1) on the first transparent conductive layer to form a first resist layer; and
(v) applying a visible-light sensitive composition (C2) on the second transparent conductive layer to form a second resist layer.

A third aspect of the present invention is a double-side photolithographic method for manufacturing a transparent conductive laminate, comprising:
(A) providing the transparent conductive substrate of the present invention;
(B) simultaneously exposing the first resist layer by a first light source and the second resist layer by a second light source;
(C) developing a first resist pattern and a second resist pattern simultaneously by removing the unexposed sections of the respective resist layers;
(D) etching the portions of the first transparent conducive layer and the second transparent conductive layer that are unprotected by the respective resist patterns simultaneously; and
(E) stripping the first resist pattern and the second resist pattern simultaneously to obtain a transparent conductive laminate;
wherein
the transparent conductive laminate comprises a first conductive circuit and a second conductive circuit on each side of a transparent core, and the design patterns of the first conductive circuit and the second conductive circuit are different from each other;
the first light source and the second light source are positioned on the opposite side of the transparent conductive substrate;
the first light source irradiates light rays with a wavelength of below 400 nm and at a targeted exposure energy to patternize the first resist layer, so that the second resist layer is substantially free from being patternized by the first light source;
the second light source irradiating light rays with a wavelength between 400 nm to 800 nm and at a targeted exposure energy for the second resist layer, so that the first resist layer is substantially free from being patternized by light rays irradiated by the second light source.

### BRIEF DESCRIPTION OF THE DRAWINGS

Embodiments of the disclosure are illustrated by way of example and not limitation in the figures of the accompanying drawings in which like references indicate similar elements.

FIG. 1 is a cross-sectional view illustrating a transparent conductive substrate according to some embodiments of the present invention.

FIG. 2 is a cross-sectional view illustrating a transparent conductive substrate according to some embodiments of the present invention.

FIG. 3 is an explanatory diagram of an example of the double-side photolithographic method for manufacturing a transparent conductive laminate according to an embodiment of the present invention.

FIG. 4 are photographs taken on the first side of the transparent conductive laminates manufactured by the present the double-side photolithographic method. FIG. 4A shows the processed transparent conductive substrate of E2, FIG. 4B shows the processed transparent conductive substrate of E7, and FIG. 4C shows the processed transparent conductive substrate of CE5.

### DETAILS OF THE INVENTION

All publications, patent applications, patents and other references mentioned herein, if not otherwise indicated, are explicitly incorporated by reference herein in their entirety for all purposes as if fully set forth.

Unless otherwise defined, all technical and scientific terms used herein have the same meaning as commonly understood by one of ordinary skill in the art to which this invention belongs. In case of conflict, the present specification, including definitions, will control.

Unless stated otherwise, all percentages, parts, ratios, etc., are by weight.

As used herein, the term “produced from” is synonymous to “comprising”. As used herein, the terms “comprises,” “comprising,” “includes,” “including,” “has,” “having,” “contains” or “containing,” or any other variation thereof, are intended to cover a non-exclusive inclusion. For example, a composition, process, method, article, or apparatus that comprises a list of elements is not necessarily limited to only those elements but may include other elements not expressly listed or inherent to such composition, process, method, article, or apparatus.

The transitional phrase “consisting of” excludes any element, step, or ingredient not specified. If in the claim, such a phrase would close the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition, method or apparatus that includes materials, steps, features, components, or elements, in addition to those literally discussed, provided that these additional materials, steps features, components, or elements do not materially affect the basic and novel characteristic(s) of the claimed invention. The term “consisting essentially of” occupies a middle ground between “comprising” and “consisting of”.

The term “comprising” is intended to include embodiments encompassed by the terms “consisting essentially of” and “consisting of”. Similarly, the term “consisting essentially of” is intended to include embodiments encompassed by the term “consisting of”.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. For example, when a range of “1 to 5” is recited, the recited range should be construed as including ranges “1 to 4”, “1 to 3”, “1-2”, “1-2 & 4-5”, “1-3 & 5”, and the like. Where a range of numerical values is recited herein, unless otherwise stated, the range is intended to include the endpoints thereof, and all integers and fractions within the range.

As used herein, the terms “a” and “an” include the concepts of “at least one” and “one or more than one”. Unless stated otherwise, all percentages, parts, ratios, etc., are by weight.

When the term “about” is used in describing a value or an end-point of a range, the disclosure should be understood to include the specific value or end-point referred to.

Further, unless expressly stated to the contrary, “or” refers to an inclusive “or” and not to an exclusive “or”. For example, a condition A “or” B is satisfied by any one of the following: A is true (or present) and B is false (or not present), A is false (or not present) and B is true (or present), and both A and B are true (or present).

The term “substantially free from” refers to less than 5%, or less than 3%, or less than 1%, or the resist being patternized.

The term “(meth)acrylic acid” means acrylic acid or methacrylic acid, the term “(meth)acrylate” means an acrylate or a corresponding thereto methacrylate. Similarly, the term “(meth)acryloyloxy group” means an acryloyloxy group or a methacryloyloxy group.

The term “(poly)ethyleneoxy” means at least one of an ethyleneoxy group or a polyethyleneoxy group in which two or more ethylene groups are linked via an ether bond. The ethyleneoxy group is a group represented by (—CH₂CH₂—O—), and also referred to as “oxyethylene group” or “ethylene oxide.” The term “(poly)propyleneoxy group” as used herein means at least one of a propyleneoxy group or a polypropyleneoxy group in which two or more propylene groups are linked via an ether bond. The propyleneoxy group is a group represented by (—CHCH₃CH₂—O—), a group represented by (—CH₂CHCH₃—O—), or a group represented by (—CH₂CH₂CH₂—O—), and also referred to as “oxypropylene group” or “propylene oxide.” The term “EO-modified” compound means a compound having a (poly)ethyleneoxy group; “PO-modified” compound means a compound having a (poly)propyleneoxy group; and “EO, PO-modified” compound means a compound having both a (poly)ethyleneoxy group and a (poly)propyleneoxy group.

The terms “sheet”, “layer” and “film” are used in their broad sense interchangeably.

Embodiments of the present invention include any embodiments described herein, may be combined in any manner, and the descriptions of variables in the embodiments pertain not only to the photosensitive compositions of the present invention, but also to the photosensitive dry films made therefrom.

The invention is described in detail herein under.

### Transparent Conductive Substrate

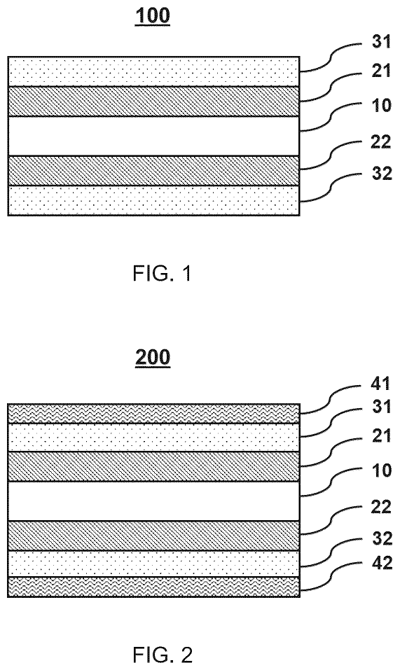

FIG. 1 is a cross-sectional view of a transparent conductive substrate according to some embodiments of the present invention. A transparent conductive substrate 100 sequentially comprises a first resist layer 31, a first transparent conductive layer 21, a transparent core 10, a second transparent conductive layer 22, and a second resist layer 32.

With respect to the transparent conductive substrate, “transparent” may refer to being capable of transmitting a substantial portion of visible light through the substrate. In some applications, “transparent” may refer to a substrate having a total transmittance in the rage of 400 nm-800 nm (T₄₀₀₋₈₀₀) being 60% or more, or 70% or more. However, other transmittance values may be desirable such as 75% or more for touch sensor applications.

A wide variety of transparent cores may be used in the present transparent conductive substrate. For example, the transparent core may be a sheet of glass, flexible glass, or quartz; or a polymeric film composed of polyethylene terephthalate (PET), polybutylene terephthalate (PBT), polyethylene naphthalate (PEN), cellulose acetate, polyethylene (PE), polypropylene (PP), cyclic polyolefin, poly(meth)acrylate ester, polyacrylate, polyamide, polyimide, polycarbonate, poly(ether sulfone), polysulfone, or combinations thereof.

The transparent core 10 generally has a thickness of 1 μm to 200 μm, or 5 μm to 100 μm, or 10 μm to 50 μm.

The first transparent conductive layer 21 and the second transparent conductive layer 22 each independently contains a conductive material that generally has a resistance value ranging from 10 ohms to 150 ohms.

The conductive material is not particularly limited, but examples thereof include fine particles of metal oxides such as zinc oxide, barium oxide, indium tin oxide (ITO), indium zinc oxide (IZO), indium gallium zinc oxide (IGZO), zirconium oxide, ytterbium oxide, yttrium oxide, tantalum oxide, aluminum oxide, cerium oxide, and titanium oxide. Among them, ITO, IZO, and IGZO are particularly preferable from the viewpoint of achieving both high transparency and conductivity. Typically, the fine particles of metal oxides preferably have a particle size of 10 μm or less, or 1.0 μm or less, or 50 nm to 150 nm.

Other suitable conductive material includes carbon nanotubes, and metal nanowires, which are wire-like conductive metals. Specific examples of a metal for the metal nanowires include iron, cobalt, nickel, copper, zinc, ruthenium, rhodium, palladium, silver, cadmium, osmium, iridium, platinum, and gold. Nanowires of copper, silver, platinum, and gold are preferred in view of conductivity. Each of the metal nanowires has at least one cross-sectional dimension of less than 500 nm, or less than 200 nm, or less than 100 nm. Each of the metal nanowires has an aspect ratio of more than 10, or more than 50, or more than 100. The shape and size of each metal nanowire may be determined with a scanning electron microscope or transmission electron microscope.

In one embodiment of the present invention, each of the first transparent conductive layer and the second transparent conductive layer independently contains a conductive material selected from composed of indium tin oxide, indium zinc oxide, indium gallium zinc oxide; carbon nanotubes; and nanowires of copper, silver, platinum, or gold.

The conductive materials constituting the first transparent conductive layer 21 and the second transparent conductive layer 22 may be the same or different. When the conductive materials constituting the transparent conductive layers 21 and 22 are the same, then the transparent conductive layers 21 and 22 may be formed on both sides of the transparent core 10 simultaneously. The first conductive layer 21 and the second transparent conductive layer 22 of the present invention maybe formed by applying a dispersion containing the conductive material on one or both surfaces of the transparent core 10 by spin coating, dipping, or chemical vapor deposition (CVD).

Each transparent conductive layer 21 or 22 has a thickness of 0.001 μm to 10 μm, or 0.01 μm to 7 μm, or 0.1 μm to 5 μm.

### Resist Layers

The first resist layer 31 is composed of a UV-light sensitive composition (C1), and C1 is patternized by exposing to light rays having a wavelength of below 400 nm. The second resist layer 32 is composed of a visible-light sensitive composition (C2) and C2 is patternized by exposing to light rays in a wavelength region of 400 nm to 800 nm.

The UV-light sensitive composition (C1) comprises:
(a) 30-70% by weight of an alkali-soluble polymer;
(b) 10-70% by weight of a polymerizable compound having an ethylenic unsaturated double bond;
(c) 0.1-20% by weight of a photoinitiator;
(d1) 0-20% by weight of a UV-absorbing sensitizer having maximum absorption in the UV-light region; and
(e) 0-20% by weight of other additives; and
(f) 0-20% by weight of a visible-light blocking material by absorbing incident visible-light energy.

The visible-light sensitive composition (C2) comprises:
(a) 30-70% by weight of an alkali-soluble polymer;
(b) 10-70% by weight of a polymerizable compound having an ethylenic unsaturated double bond;
(c) 0.1-20% by weight of a photoinitiator;
(d2) 0.01-20% by weight of a visible-light absorbing sensitizer having maximum absorption in the visible-light region; and
(e) 0-20% by weight of other additives; and
(g) 0.01-20% by weight of a UV-light blocking material by absorbing incident UV-light energy.

Hereinafter, each component which may be included in the UV-light sensitive composition and/or the visible-light sensitive composition of the disclosure will be described.

### Alkali-Soluble Copolymer (a)

As the component (a), an alkali-soluble polymer generally is a polymer having an acidic group (e.g., a carboxylic acid group, a sulfonic acid group, or a phosphoric acid group). Preferably, the alkali-soluble polymer is derived from a polymerizable precursor containing carboxylic acid group(s). Examples of the polymerizable precursor containing carboxylic acid group(s) include (meth)acrylic acid, maleic acid, fumaric acid, itaconic acid, crotonic acid, cinnamic acid, α-cyanocinnamic acid, propiolic acid; maleic anhydride, phthalic anhydride, itaconic anhydride, citraconic anhydride, and the like. In view of cost and solubility, (meth)acrylic acid is preferred.

The alkali-soluble polymer (a) may also comprise structural unit derived from polymerizable precursors not having carboxylic acid groups.

Examples of the polymerizable precursors not having carboxylic acid groups include (meth)acrylic esters, crotonic esters, vinyl esters, maleic diesters, fumaric diesters, itaconic diesters, (meth)acrylamides, vinyl ethers, esters of vinyl alcohol, styrene, substituted styrenes, (meth)acrylonitrile, vinyl-substituted heterocyclic compounds, N-vinylamides, sulfonic acids having vinyl group, phosphoric esters having vinyl group, urethanes having vinyl group, ureas having vinyl group, sulfonamides having vinyl group, phenols having vinyl group, and imides having vinyl group.

Examples of (meth)acrylate esters include alkyl (meth)acrylates, cycloalkyl (meth)acrylates, benzyl (meth)acrylate, or the like. The alkyl (meth)acrylates are preferably ester of an alkyl group having from 1 to 5 carbon atoms. Examples of alkyl (meth)acrylate include methyl (meth)acrylate, ethyl (meth)acrylate, propyl (meth)acrylate, butyl (meth)acrylate, pentyl (meth)acrylate, and mixtures thereof.

Examples of other (meth)acrylate esters include furfuryl (meth)acrylate, tetrahydrofurfuryl (meth)acrylate, isobornyl (meth)acrylate, adamantyl (meth)acrylate, dicyclopentanyl (meth)acrylate, dimethylaminoethyl (meth)acrylate, diethylaminoethyl (meth)acrylate, glycidyl (meth)acrylate, 2,2,2-trifluoroethyl (meth)acrylate, 2,2,3,3-tetrafluoropropyl (meth)acrylate, dicyclopentenyloxyethyl (meth)acrylate, dicyclopentanyloxyethyl (meth)acrylate, isobonyloxyethyl (meth)acrylate, cyclohexyloxyethyl (meth)acrylate, adamantyloxyethyl (meth)acrylate, dicyclopentenyloxypropyl-oxyethyl (meth)acrylate, or the like.

In one embodiment, the alkali-soluble polymer (a) is derived from a mixture composed of 15-50% by weight of a styrene or a substituted styrene; 15-35% by weight of a (meth)acrylic acid; and 10-70% by weight of one or more (meth)acrylate esters, based on the total weight of the polymerizable precursors for constituting the alkali-soluble polymer (a).

In another embodiment, the alkali-soluble polymer (a) is derived from a mixture composed of 15-45% by weight of a styrene or a substituted styrene, 20-30% by weight of a (meth)acrylic acid, and 15-65% by weight of one or more (meth)acrylate esters, based on the total weight of the polymerizable precursors for constituting the alkali-soluble polymer (a).

In yet another embodiment, the alkali-soluble polymer (a) is derived from a mixture composed of 10-45% by weight of a styrene or a substituted styrene, 20-30% by weight of a (meth)acrylic acid, 10-60% by weight of a benzyl (meth)acrylate and 10-50% by weight of an alkyl (meth)acrylate ester, based on the total weight of the polymerizable precursors for constituting the alkali-soluble polymer (a).

The alkali-soluble polymer (a) may be obtained, for example, by radical polymerization of a mixture composed of styrene or α-methyl styrene, (meth)acrylic acid, one or more (meth)acrylate esters, and optional other polymerizable precursors, using an ordinary method.

The weight-average molecular weight (Mw) of the polymeric binder measured by gel permeation chromatography (GPC) (calculated based on a calibration curve produced using polystyrene standards) is preferably from 25,000 to 100,000, more preferably from 30,000 to 80,000, and most preferably from 40,000 to 60,000.

The dispersity (weight average molecular weight/number average molecular weight, Mw/Mn) of the alkali-soluble polymer (a) is preferably 3.0 or less, more preferably 2.8 or less, and still more preferably 2.5 or less.

The acid value of the alkali-soluble polymer (a) is preferably from 90 mg KOH/g to 250 mg KOH/g, more preferably from 100 mg KOH/g to 240 mg KOH/g, and still more preferably from 120 mg KOH/g to 235 mg KOH/g.

The amount of the alkali-soluble polymer (a) in the UV-light sensitive composition (C1) or the visible-light sensitive composition (C2) is typically 30-70% by weight, preferably 35-65% by weight, and more preferably 40-60% by weight, based on the total weight of the respective composition.

### Polymerizable Compound (b)

The UV-light sensitive composition or the visible-light sensitive composition each comprises a polymerizable compound as the component (b) that is capable of undergoing free-radical initiated polymerization and/or crosslinking. Such compounds are well known in the art and may be referred to as “monomers” hereunder. The monomer has at least one ethylenically unsaturated bond, and is not particularly limited as long as it is a photopolymerizable compound. Suitable monomers which may be used as the sole monomer or in combination with others.

The polymerizable compound (b) may be a (meth)acrylate compound selected from the group consisting of butyl (meth)acrylate, ethylhexyl (meth)acrylate, 2-ethoxyethyl (meth)acrylate, cyclohexyl (meth)acrylate, 2-propylheptyl (meth)acrylate, lauryl (meth)acrylate, stearyl (meth)acrylate, behenyl (meth)acrylate, alkoxylated phenol (meth)acrylate, alkoxylated nonylphenol (meth)acrylate, nonylphenol (meth)acrylate, isobornyl (meth)acrylate, cyclic trimethylolpropane formal (meth)acrylate, dihydrodicyclopentadienyl (meth)acrylate, dicyclopentadienyl (meth)acrylate, caprolactone (meth)acrylate, 2-phenoxyethyl (meth)acrylate, o-phenylphenoxyethyl (meth)acrylate, benzyl (meth)acrylate, monomethoxy tri(propylene glycol) mono(meth)acrylate, polypropoxylated propylene glycol mono(meth)acrylate, monomethoxy neopentyl glycol propoxylate mono(meth)acrylate, tetrahydrofurfuryl (meth)acrylate, isooctyl (meth)acrylate, isodecyl (meth)acrylate, tridecyl (meth)acrylate, 2-(2-ethoxyethoxy)ethyl (meth)acrylate, acetoacetoxyethyl (meth)acrylate, cyclopentenyl oxyethyl (meth)acrylate, 9-anthracenyl methyl (meth)acrylate, 1-pyrenylmethyl (meth)acrylate, lauryl (meth)acrylate, and a combination thereof.

The polymerizable compound (b) may be a di(meth)acrylate compound selected from the group consisting of 1,3-butanediol di(meth)acrylate, 1,4-butanediol di(meth)acrylate, 1,6-hexanediol di(meth)acrylate, 1,8-octanediol di(meth)acrylate, 1,10-decanediol di(meth)acrylate, polybutadiene di(meth)acrylate, ethylene glycol di(meth)acrylate, propylene glycol di(meth)acrylate, neopentyl glycol di(meth)acrylate, diethylene glycol di(meth)acrylate, tri(ethylene glycol) di(meth)acrylate, tetra(ethylene glycol) di(meth)acrylate, poly(ethylene glycol) di(meth)acrylate, di(propylene glycol) di(meth)acrylate, tri(propylene glycol) di(meth)acrylate, tetra(propylene glycol) di(meth)acrylate, poly(propylene glycol) di(meth)acrylate, glyceryl ethoxylate di(meth)acrylate, glyceryl propoxylate di(meth)acrylate, tricyclodecanedimethanol di(meth)acrylate, neopentylglycol ethoxylate di(meth)acrylate, neopentylglycol propoxylate di(meth)acrylate, bisphenol A ethoxylate di(meth)acrylate, bisphenol A propoxylate di(meth)acrylate, bisphenol A ethoxylate propoxylate di(meth)acrylate, and a combination thereof.

The polymerizable compound (b) may be a poly(meth)acrylate compound selected from the group consisting of trimethylolpropane tri(meth)acrylate, trimethylolpropane ethoxylate tri(meth)acrylate, trimethylolpropane propoxylate tri(meth)acrylate, glyceryl tri(meth)acrylate, tri(meth)acrylate, glyceryl ethoxylate tri(meth)acrylate, glyceryl propoxylate tri(meth)acrylate, pentaerythritol tri(meth)acrylate, tris(2-hydroxyethyl)isocyanurate tri(meth)acrylate, pentaerythritol tetra(meth)acrylate, pentaerythritol ethoxylate tetra(meth)acrylate, pentaerythritol propoxylate tetra(meth)acrylate, di-trimethylolpropane tetra(meth)acrylate, di-trimethylolpropane ethoxylate tetra(meth)acrylate, di-trimethylol-propane propoxylate tetra(meth)acrylate, dipentaerythritol penta(meth)acrylate, dipentaerythritol ethoxylate penta(meth)acrylate, dipentaerythritol hexa(meth)acrylate, and a combination thereof.

Preferred polymerizable compounds include polypropoxylated propylene glycol di(meth)acrylate, triethylene glycol di(meth)acrylate, trimethylolpropane tri(meth)acrylate, polyethoxylated trimethylolpropane tri(meth)acrylate, and mixtures thereof.

Other preferred polymerizable compounds include bisphenol A type (meth)acrylates include 2,2-bis(4-((meth)acryloyloxypolyethoxy)phenyl)propane, 2,2-bis(4-((meth)acryloyloxypolypropoxy)-phenyl)propane, 2,2-bis(4-((meth)acryloyloxypolybutoxy)phenyl)propane, and 2,2-bis(4-((meth)-acryloyloxypolyethoxypolypropoxy)phenyl)propane. Among them, 2,2-bis(4-((meth)acryloyl-oxypolyethoxy)phenyl)propane is preferable from the viewpoints of further improving resolution and peeling properties.

In one embodiment, the component (b) comprises a polymerizable compound having two or more methacryloyl groups in one molecule.

In another embodiment, the component (b) comprises polyethoxylated bisphenol A di(meth)acrylate, polypropoxylated bisphenol A di(meth)acrylate, polyethoxylated-polypropoxylated bisphenol A di(meth)acrylate, or combinations thereof.

Commercially available bisphenol A type (meth)acrylates include, for example, BPE-200 and BPE-500 (manufactured by Shin-Nakamura Chemical Co., Ltd.), and BPE-900 (manufactured by Sartomer).

Examples of commercially available polymerizable compounds include polyethoxylated bisphenol A type (meth)acrylates (e.g., “BPE-200” and “BPE-500” manufactured by Shin-Nakamura Chemical Co. Ltd.), or “FA-324M” manufactured by Hitachi Chemical Co., Ltd.); hydroxyl group-containing alkyl acrylate (e.g., “701A” manufactured by Shin-Nakamura Chemical Co., Ltd); tricyclodecane dimethanol diacrylate (e.g., “A-DCP” manufactured by Shin-Nakamura Chemical Co., Ltd.); polypropylene glycol diacrylate (e.g., “9PG” manufactured by Shin-Nakamura Chemical Co., Ltd.); polyethylene glycol methacrylate (e.g., “14G” manufactured by Shin-Nakamura Chemical Co., Ltd); 2,2-bis(4-(methacryloxy-polyethoxypolypropoxy)phenyl) propane (e.g., “FA-3200MY” manufactured by Hitachi Chemical Co., Ltd.); tetramethylolmethane triacrylate (e.g., “A-TMM-3” manufactured by Shin-Nakamura Chemical Co., Ltd.); polyethoxylated trimethylolpropane trimethacrylate (e.g., “TMPT21E”, “TMPT30E” manufactured by Hitachi Chemical Co., Ltd); pentaerythritol triacrylate (e.g., “SR444” manufactured by Sartomer); dipentaerythritol hexaacrylate (e.g., “A-DPH” manufactured by Shin-Nakamura Chemical Co., Ltd.); and polyethoxylated pentaerythritol tetraacrylate (e.g., “ATM-35E” manufactured by Shin-Nakamura Chemical Co., Ltd).

The amount of the polymerizable compounds (b) in the UV-light sensitive composition (C1) or visible-light sensitive composition (C2) is typically 10-70% by weight, preferably 20-60% by weight, and more preferably 30-50% by weight, based on the total weight of the respective composition.

### Photoinitiator (c)

As the component (c), the photoinitiator (c) is not particularly limited, and appropriately selected from conventionally employed photoinitiators.

Examples of such a photoinitiator is not particularly limited, but include acetophenone compounds such as 2,2-diethoxyacetophenone, 2-methyl-1-[4′-(methylthio)-2-morpho-linopropiophenone, 1-hydroxycyclohexyl phenyl ketone, 4-(2-hydroxy-ethoxy)phenyl-2-hydroxy-2-propyl ketone, 1-(4-dodecylphenyl)-2-hydroxy-2-methyl-1-propanone, 2-hydroxy-2-methyl-1-phenyl-1-propanone, 2-methyl-1-(4-methylthiophenyl)-2-morpho-linopropan-1-one, 2-benzyl-2-dimethylamino-1-(4-morpholinophenyl)-1-butanone, 2-dimethylamino-2-(4-methyl-benzyl)-1-(4-morpholin-4-yl-phenyl)-butan-1-one; benzoin compounds such as benzoin, benzoin methyl ether, benzoin ethyl ether, benzoin isopropyl ether, benzoin isobutyl ether, 2,2-dimethoxy-2-phenylacetophenone; hexaaryl-biimidazole compounds, abbreviated as “HABI”, such as 2,2′-bis(2-chlorophenyl)-4,4′,5,5′-tetraphenyl-1,2′-biimidazole (o-Cl-HABI), 2,2′,4-tris(2-chlorophenyl)-5-(3,4-dimethoxyphenyl)-4′,5′-diphenyl-1,1′-biimidazole (TCDM-HABI), and 2,2′-bis(2-ethoxy-phenyl)-4,4′,5,5′-tetraphenyl-2H-1,2′-biimidazole; benzoylphosphine oxide compounds such as diphenyl(2,4,6-trimethylbenzoyl)phosphine oxide, and phenyl bis(2,4,6-trimethyl-benzoyl)phosphine oxide; oxime ester compounds such as 1-[4-(phenylthio)phenyl]-1,2-octanedione 2-(O-benzoyloxime), 1-[9-ethyl-6-(2-methylbenzoyl)-9H-carbazol-3-yl]ethanone 1-(O-acetyloxime) (Irgacure OXE02), and 3-cyclopentyl-1-[9-ethyl-6-(2-methyl-benzoyl)-9H-carbazol-3-yl]-1-propanone-1-(O-acetyloxime).

These photopolymerization initiators may be used alone or in combination of two or more.

In one embodiment, the photoinitiator (c) comprises a hexaarylbiimidazole compound, a benzoylphosphine oxide compound, an oxime ester compound, or combinations thereof.

In another embodiment, the photoinitiator (c) comprises o-Cl-HABI, TCDM-HABI, and a mixture thereof.

Suitable photoinitiators are commercially available, for example, o-CI-HABI and TCDM-IABI may be purchased from Flampford Research Inc.; benzoylphosphine oxide compounds from IGM Resins USA Inc.; oxime ester compounds from Changzhou Tronly New Electronic Materials Co., Ltd.

The amount of the photoinitiator (c) in the UV-light sensitive composition (C1) or visible-light sensitive composition (C2) is typically 0.1-20% by weight, preferably 0.5-10% by weight, and more preferably 1-5% by weight, based on the total weight of the respective composition.

### UV-Absorbing Sensitizer (d1)

As a sensitizer suitable for use in the UV-light sensitive composition (C1), the UV-absorbing sensitizer (d1) has a maximum absorption in the UV-light region, i.e., <400 nm; preferably, from 300 nm to 400 nm to provide additional absorption in the UV-light region.

Suitable UV-absorbing sensitizers (d1) include aromatic ketones such as benzophenone, 4-aminobenzophenone, 4,4′-diaminobenzophenone, 4,4′-dimethoxy-benzophenone, (4-(dimethylamino)phenyl)phenyl methanone, (4-(diethylamino)phenyl)-phenyl methanone, N,N,N′,N′-tetramethyl-4,4′-diaminobenzophenone, N,N,N′,N′-tetraethyl-4,4′-diaminobenzophenone, 4-methoxy-4′-dimethylamino-benzophenone, 4-benzoyl-4′-methyl diphenyl sulfide; acridine compounds such as 9-phenylacridine, and 1,7-bis(9,9′-acridinyl)heptane; aromatic sulfone compounds such as sulfonyl dibenzene, 4,4′-sulfonylbis(N,N-dimethyl-benzenamine), 4,4′-sulfonylbis(N,N-diphenylbenzenamine), and 9,9′-(sulfonyldi-4,1-phenylene)bis-9H-carbazole.

The amount of the UV-absorbing sensitizer (d1) in the UV-light sensitive composition (C1) is 0-20% by weight, or 0.01-10% by weight, or 0.1-5% by weight, based on the total weight of the UV-light sensitive composition.

### Visible-Light Absorbing Sensitizer (d2)

As a sensitizer suitable for use in the visible-light sensitive composition (C2), the visible-light absorbing sensitizer (d2) is expected to extend the spectral response of the photoinitiator (c), and preferably with a maximum absorption wavelength in the visible light region of 400 nm to 700 nm.

Examples of the visible-light absorbing sensitizers (d2) include ketones, coumarins, xanthones, oxazoles, benzoxazoles, thiazoles, benzothiazoles, triazoles, stilbenes, triazines, thiophenes, naphthalimide compounds, bis(p-dialkylaminobenzylidene) ketones and arylidene aryl ketones.

Preferred visible-light absorbing sensitizers (d2) include 1,3-bis(1,3-dihydro-1,3,3-trimethyl-2H-indol-2-ylidene)-2-propanone (Bis-Fischer's Base Ketone, BFBK), 3-benzoyl-7-(diethylamino)-2H-1-benzopyran-2-one, 3-benzoyl-7-diethylaminocoumarin, 7-(diethylamino)-3-(7-(diethylamino)-2-oxochromane-3-carbonyl)-2H-chromen-2-one, 3-(2-N-methylbenzimidazolyl)-7-N,N-diethylaminocoumarin, 3-(2-benzothiazolyl)-7-(diethylamino)coumarin, 3-(2-benzoxazolyl)-7-(diethylamino)coumarin, (E)-1-phenyl-3-(2,3,6,7-tetrahydro-1H,5H-benzo[ij]quinolizin-9-yl)-2-propen-1-one (juloidine chalcone), 4-(dimethylamino)chalcone, (2E,5E)-2,5-bis[4-(dimethylamino)benzylidene]-cyclopenta-none, (2E,5E)-2,5-bis[4-(diethylamino)benzylidene]-cyclopentanone, and ketocyanine dyes.

Suitable visible-light absorbing sensitizers (d2) are commercially available, for example, Bis-Fischer's Base Ketone may be purchased from Hampford Research Inc; 3-benzoyl-7-(diethylamino)-2H-1-benzopyran-2-one may be purchased from Changzhou Tronly New Electronic Materials Co., Ltd.

The amount of the visible-light absorbing sensitizer (d2) in the visible-light sensitive composition (C2) is 0.01-20% by weight, or 0.05-10% by weight, or 0.1-5% by weight, based on the total weight of the visible-light sensitive composition (C2).

### Other Additives (e)

Other compounds conventionally added to photosensitive compositions may also be present in the UV-light sensitive composition or the visible-light sensitive composition. Such additives include: hydrogen donors, adhesion modifiers, coloring substance, leveling agent, plasticizers, surfactants, stabilizing agents, anti-oxidants, polymerization inhibitors, cross-linking agents, and the like.

A hydrogen donor may be added to improve the sensitivity and the contrast between an exposed area and an unexposed area of the photosensitive composition after exposing to active light rays. The specific species is not particularly limited as long as the hydrogen donor has the above-mentioned characteristics, and may be selected but not limited to: amine compounds, carboxylic acid compounds, mercapto-containing compounds, alcohol compounds, and the like.

The amine compounds include but not limited to aliphatic amine compounds such as triethanolamine, methyl diethanolamine, triisopropanolamine, n-butylamine, and the like; aromatic amine compounds such as methyl 4-dimethylaminobenzoate, ethyl 4-dimethylaminobenzoate, isoamyl 4-dimethyl-aminobenzoate, 2-ethylhexyl 4-(dimethyl-amino)-benzoate, 2-butoxyethyl 4-(dimethyl-amino)benzoate, 2-dimethylaminoethyl-benzoate, N-dimethyl-p-toluidine, 4,4′-bis(dimethyl-amino)benzophenone, 4,4′-bis(diethyl-amino) benzophenone (Michler's ketone), and the like.

The carboxylic acid compounds include but not limited to aromatic heteroacetic acid such as (phenylthiol)acetic acid, methylphenylthioacetic acid, ethylphenylthioacetic acid, methylethylphenylthioacetic acid, dimethylphenylthioacetic acid, methoxyphenylthioacetic acid, dimethoxyphenylthioacetic acid, chlorophenylthioacetic acid, dichlorophenylthioacetic acid, N-phenylglycine, phenoxyacetic acid, naphthylthioacetic acid, N-naphthylglycine, naphthyloxyacetic acid, and the like.

The mercapto-containing compounds include but not limited to 2-mercapto-benzothiazole, 2-mercaptobenzimidazole, dodecylmercaptan, octanediol bis(3-mercapto-butyrate), trimethylolpropane tris(3-mercaptobutyrate), pentaerythritol tetrakis(3-mercapto-butyrate), dipentaerythritol hexa(3-mercaptobutyrate); ethylene glycol bis(2-mercapto-propionate), propylene glycol bis(2-mercaptopropionate), propylene glycol bis(2-mercapto-propionate), propylene glycol bis(2-mercaptopropionate), and the like.

The alcohol compounds include but not limited to methanol, ethanol, 1-propanol,2-propanol, 1-butanol, 2-butanol, neopentyl alcohol, n-hexanol, cyclohexanol, ethylene glycol, 1,2-propanediol, 1,2,3-propanetriol, benzyl alcohol, phenethyl alcohol, and the like.

The amount of the hydrogen donor may be 0 to 20 parts by weight, preferably 0.01 to 10 parts by weight, in 100 parts by weight of the UV-light sensitive composition or the visible-light sensitive composition. When the amount of the hydrogen donor is within the above range, it is advantageous to control the sensitivity of the photosensitive resin composition.

An adhesion modifier may be added to improve adhesion of the coating to substrates and or prevent residue formation during processing. Suitable adhesion modifiers include heterocyclic chelating components such as benzotriazole, 5-chloro-1H-benzotriazole, 1-chloro-1H-benzotriazole, 4- and 5-carboxy-1H-benzotriazole, 1-hydroxy-1H-benzo-triazole, 2-mercaptobenzoxazole, 1H-1,2,4-triazole-3-thiol, 5-amino-1,3,4-thiodiazole-2-thiol, 2-mercaptobenzimidazole, and the like. Citric acid is an example of a non-heterocyclic chelating compound that is effective in this manner, i.e. to improve adhesion of the coating and or prevent residue formation.

Examples of the coloring substance include fuchsin, phthalocyanine green, auramine base, paramadienta, leuco crystal violet (LCV), methyl orange, nile blue 2B, victoria blue, malachite green chloride salt (Sigma-Aldrich), basic blue 20, diamond green (Hodogaya Chemical Co., Ltd.), and the like.

Examples of leveling agents include fluorine-based compounds, silicone-based compounds, and acrylic compounds.

Examples of plasticizers include phthalic acid ester such as dimethyl phthalate and diethyl phthalate, trimellitic acid ester such as tris(2-ethylhexyl)trimellitate; aliphatic dibasic acid ester such as dimethyl adipate and dibutyl adipate; orthophosphoric acid ester such as tributyl phosphate and triphenyl phosphate; and acetic acid ester such as glyceryl triacetate and 2-ethylhexyl acetate.

A surfactant may be added to improve coating properties of the photosensitive composition. Examples of surfactants include polyoxyethylene octylphenyl ether, polyoxy ethylene nonyl phenylether, F171, F172, and F173 (available from Dainippon Ink & Chemicals, Japan), FC430 and FC431 (available from Sumitomo 3M Ltd., Japan), KP341 (available from Shinetsu Chemical Co., Japan), among others.

Examples of stabilizing agents include hindered amine-based compounds, and benzoate-based compounds. Examples of anti-oxidants include phenol-based compounds. Examples of polymerization inhibitors include methoquinone, methylhydroquinone, and hydroquinone. Examples of cross-linking agents include polyisocyanates, and melamine compounds.

The other additives (e) are generally present in minor amounts (i.e., less than 10% by weight) so as not to interfere with the functional properties of the present photosensitive composition.

### Visible-Light Blocking Material (f)

Component (f) is a visible-light blocking material that absorbs visible light and may be added to the UV-light sensitive composition (C1). Visible light absorbing materials include organic substances such as dyes or pigments; inorganic substances such as metal oxide particles, and a metal complex of an organic substance. Examples of such visible light absorbing materials include by but are not limited to those disclosed in D. L. Jinkerson, U.S. Pat. No. 5,662,707.

Suitable visible-light absorbing materials include but not limited to methine compounds, such as Eastman Yellow 035-MA (Eastman Chemical), ketimide compounds, naphthoyl asia amines, nitrodiphenylamine compounds, aminoketone compounds, nitro compounds, anthraquinone compounds, quinoline compounds, benzothiazole compounds, benzimidazole compounds, benzanthracene compounds; and azo metal complexing compounds.

Example of metal oxide particles including nanoparticles of TiO₂, CoO and Fe₂O₃. The diameter of the nanoparticles generally ranges from 20 nm to 50 nm with visible-light absorption character.

Examples of commercially available visible-light blocking materials include pigments such as azo yellow pigment (e.g., Hansa Yellow 10G manufactured by Clariant), naphthol yellow pigment (e.g., Permanent Yellow manufactured by Clariant), benzimidazolone yellow pigment (e.g., C.I. Yellow 154 manufactured by Arichemie GmbH), azo condensation yellow pigment (e.g., Cromophtal Yellow 3G manufactured by BASF), and the like.

Other commercially available visible-light blocking materials include dyes such as Eusorb UV1990, Eusorb UV-1995, and Eusorb UV-4000 are manufactured by Eutec chemical Co., Ltd.; ANSORB-460, ANSORB-475 and ANSORB-930 are manufactured by Anchem Technology Corporation.

The visible-light blocking material may contain more than one substance. By adding a plurality of visible-light absorbing substances as the component (f), the UV-light sensitive composition (C1) is prohibited from photopolymerization by visible-light exposure between 400 nm to 800 nm.

### UV-Light Blocking Material (g)

Component (g) is a UV-light blocking material that absorbs UV light and is added to the visible-light sensitive composition (C2). For example, the UV-light blocking material may be tuned to block light rays in the UV region of the electromagnetic spectrum, approximately 200 nm to 400 nm.

Suitable UV-light blocking material (g) include benzophenone compounds, benzotriazole compounds, triazine compounds, compounds with a polymerizable moiety, and nanoparticles.

Example of benzophenone compounds include but not limited to 2,4-dihydroxy-benzophenone, 2-hydroxy-4-methoxybenzophenone, 2-hydroxy-4-n-(octyloxy)benzo-phenone, 2,2′,4,4′-tetrahydroxybenzophenone, 2,2′-dihydroxy-,4,4′-dimethoxybenzo-phenone, and the like.

Example of benzotriazole compounds include but not limited to octyl-3-[3-tert-butyl-4-hydroxy-5-(5-chloro-2H-benzotriazole-2-yl)phenyl]propionate, 2-ethylhexyl-3-[3-tert-butyl-4-hydroxy-5-(5-chloro-2H-benzotriazole-2-yl)phenyl]propionate, 2-(2H-benzo-triazol-2-yl)-4,6-bis(1-methyl-1-phenylethyl)phenol, 2-(2′-hydroxy-5′-tert-butylphenyl)-benzotriazole, 2-(2-hydroxy-5-methylphenyl)benzotriazole, 2-(2-hydroxy-5-tert-octyl-phenyl)benzotriazole, 2-(2-hydroxy-3-tert-butyl-5-methylphenyl)-5-chlorobenzotriazole, 2-(2H-benzotriazol-2-yl)-4,6-di-tert-pentylphenol, 2-(3,5-di-tert-butyl-2-hydroxyphenyl)-5-chloro-2H-benzotriazole, 2-[2H-benzotriazol-2-yl]-4,6-bis(1-methyl-1-phenylethyl)phenol, 2-(2′-hydroxy-3′5-di-tert-butylphenyl) benzotriazole, 2-(3,5-di-tert-amyl-2-hydroxyphenyl)-benzotriazole, and the like.

Example of triazine compounds include but not limited to 2-[4-[2-hydroxy-3-tridecyloxypropyl]oxy]-2-hydroxyphenyl]-4,6-bis(2,4-di-methylphenyl)-1,3,5-triazine, 2-[4-[2-hydroxy-3-didecyloxy-propyl]oxy]-2-hydroxyphenyl]-4,6-bis-(2,4-dimethylphenyl)-1,3,5-triazine, 2-(4,6-diphenyl-1,3,5-triazin-2-yl)-5-hexyloxy-phenol, 2-(4,6-bis(2,4-di-methylphenyl)-1,3,5-triazin-2-yl)-5-(3-((2-ethylhexyl)oxy)-2-hydroxypropoxy)-phenol, and the like.

UV-light blocking material (g) also include compounds with a polymerizable moiety such as vinyl, acrylate, or methacrylate functionality in their chemical structure.

Examples of compounds with a polymerizable moiety include but not limited to 2-hydroxy-5-methoxy-3-(5-(trifluoromethyl)-2H-benzo[d][1,2,3]triazol-2-yl)benzyl methacrylate, 3-(5-fluoro-2H-benzo[d][1,2,3]triazol-2-yl)-2-hydroxy-5-methoxybenzyl methacrylate, 3-(2H-benzo[d][1,2,3]triazol-2-yl)-2-hydroxy-5-methoxy-benzyl methacrylate, 3-(5-chloro-2H-benzo[d][1,2,3]triazol-2-yl)-2-hydroxy-5-methoxybenzyl methacrylate, 2-hydroxy-5-methoxy-3-(5-methoxy-2H-benzo[d][1,2,3]triazol-2-yl)benzyl meth-acrylate, 2-hydroxy-5-methoxy-3-(5-methyl-2H-benzo[d][1,2,3]triazol-2-yl)benzyl methacrylate; and 2-hydroxy-5-methyl-3-(5-(trifluoromethyl)-2H-benzo[d][1,2,3]triazol-2-yl)benzyl meth-acrylate, 2-(3-(3-(5-chloro-2H-benzo[d][1,2,3]triazol-2-yl)-4-hydroxy-5-methoxyphenyl)-propylthio)ethyl methacrylate, and 3-(4-hydroxy-3-methoxy-5-(5-(trifluoromethyl)-2H-benzo[d][1,2,3]triazol-2-yl)phenyl)propyl methacrylate; 4-allyl-2-(5-chloro-2H-benzo[d][1,2,3]triazol-2-yl)-6-methoxyphenol, 4-allyl-2-methoxy-6-(5-(trifluoro-methyl)-2H-benzo[d][1,2,3]triazol-2-yl)phenol, and 3-(4-hydroxy-3-methoxy-5-(5-(trifluoro-methyl)-2H-benzo[d][1,2,3]triazol-2-yl)phenyl)propyl methacrylate; and the like.

Examples of commercially available UV-light blocking materials include ultraviolet absorption polymers such as VANARESIN UVA-5080, UVA-7075, UVA-55T, UVA-73T, UVR-8001E, UVR-9001, NEWCOAT UVA-101, NEWCOAT UVA-102, NEWCOAT UVA-103, NEWCOAT UVA-104 manufactured by Shin-Nakamura Chemical Co., Ltd.; 2,2′,4,4′-tetrahydroxybenzophenone manufactured by from Everlight.

The amount of the UV-light blocking materials (g) is about 0.01-20.0% by weight, or about 0.05-15% by weight, or about 0.1 to 10% by weight, based on the total amount of the visible-light sensitive composition (C2). When the amount of the component (g) is within this range, it is easy to provide good UV-light blocking capability and the resolution and adhesion of the dry film resist in a well-balanced manner.

### Set of Dry Films (DF1) and (DF2)

A dry film is generally prepared by applying a photosensitive composition on a support film to form a photosensitive layer in an uncured state, and then covered with a protective film when it is stored in a roll form. The photosensitive layer may be referred as “photoresist”, “resist” or “dry film resist”, interchangeably.

As the present transparent conductive substrate comprises a first resist layer and a second resist layer, wherein the first resist layer is composed of a UV-light sensitive composition and the second resist layer is composed of a visible-light sensitive composition. Consequently, a set of dry films DF1 and DF2 is provided, wherein DF1 is a UV-light sensitive dry film and DF2 is a visible-light sensitive dry film. The set of dry films (i.e., DF1 and DF2) is suitable for manufacturing the present transparent conductive substrate that is subjected to a double-side photolithographic method for manufacturing a transparent conductive laminate.

DF1 comprises a support film, a resist layer composed of the above-mentioned UV-light sensitive composition (C1), and optionally a protective film. DF2 comprises a support film, a resist layer composed of the above-mentioned visible-light sensitive composition (C2), and optionally a protective film.

The support film is generally a polymeric film, and preferably has a high dimensional stability with a transmittance of >90% with respect to light rays in the 350 nm to 420 nm region.

The support film may be composed of polyamides, polyolefins, polyesters, vinyl polymers, and cellulose esters. A particularly suitable support film is a polymeric film composed of polyethylene terephthalate, polyethylene, or polypropylene. The thickness of the support film is from 1 μm to 100 μm, preferably from 5 μm to 50 μm, and more preferably from 10 μm to 30 μm.

The protective film may be selected from the same group of polymeric films described for the support film, supra, and may have the same wide range of thicknesses. However, the protective film is preferable to have a lower adhesion to the resist layer relative to the adhesion of the resist layer to the support film. A particularly suitable protective film is a polymeric film composed of polyethylene, polypropylene, or polyethylene terephthalate. The thickness of the protective film is from 1 μm to 100 μm, preferably from 5 μm to 50 μm, and more preferably from 10 μm to 30 μm.

Examples of commercially available polymeric film include polyethylene terephthalate films of PS series manufactured by Teijin Limited, and FB series manufactured by Toray Industries, Inc.; polyethylene films such as ALPHAN MA-410 and E-200 manufactured by Oji Paper Co., Ltd.; and a polypropylene film manufactured by Shin-Etsu Film Co., Ltd.

When the UV-light sensitive photosensitive composition or the visible-light sensitive composition is in liquid form with suitable viscosity, it may be applied onto the support film directly to form the corresponding resist layer. Preferably, the UV-light sensitive composition (C1) and the visible-light sensitive composition (C2) each is dissolved in an organic solvent to lower the viscosity and allow forming the respective resist layer with an uniform thickness.

Examples of suitable solvents include alcohols such as methanol, ethanol, propanol, butanol, and the like; ethers such as tetrahydrofuran; ketones such as acetone and methyl ethyl ketone; glycol ethers such as methylcellosolve, ethylcellosolve, and propyleneglycol monomethyl ether; aromatic hydrocarbon solvents such as toluene; aprotic polar solvents such as N,N-dimethylformamide; and mixtures thereof. The solvents may be appropriately selected depending on the solubility of the photosensitive composition.

The method for preparing the UV-light sensitive composition (C1) and the visible-light sensitive composition (C2) according to the present disclosure is not particularly limited, and these compositions may be obtained by mixing individual components contained in the respective composition by a known method.

In addition, filtration may be carried out through a filter in order to remove a foreign material or reduce defects. Any filter may be used without particular limitation as long as it has been conventionally used for filtration or the like.

In one embodiment, the UV-light sensitive dry film (DF1) and the visible-light sensitive dry film (DF2) may be manufactured by forming a resist layer by applying a coating solution containing the respective composition to a support film; and drying the resultant to form the resist layer.

The solid content of the coating solution containing the respective composition may be appropriately selected depending on the application method and tool. For example, the organic solvent may be used to give a solution with a solid content of from about 15% by weight to about 60% by weight.

The coating solution may be applied to the support film by a known method such as roll coating, comma coating, gravure coating, air knife coating, die coating, or bar coating.

The drying is preferably carried out at from 25° C. to 120° C. for about 5 minutes to about 60 minutes. The amount of the residual solvent in the photosensitive layer after drying is preferably 2% by weight or less.

The thickness of the dry films (DF1 and DF2) may be appropriately selected depending on the intended use. The post-drying thickness of the resist layer is from 0.1 m to 50 m; or from 0.2 μm to 30 m; or from 0.3 μm to 25 μm.

The shape of the resulting dry film is not particularly limited. The dry film may be a sheet form, or may be wound into a roll shape around a core. When the dry film is wound into a roll shape, it is preferable that the support film faces outside.

The set of dry films (DF1 and DF2) according to the present embodiment may be used, for example, in the method for manufacturing a transparent conductive substrate as described below.

### Method for Manufacturing a Transparent Conductive Substrate

The previously described UV-light sensitive composition (C1) and the visible-light sensitive composition (C2), and the set of dry films (DF1 and DF2) of the invention may be used to form a transparent conductive substrate.

In one embodiment, the present transparent conductive substrate 100 is manufactured by a method comprising:
(i) providing a transparent core;
(ii) forming a first transparent conductive layer on one surface of the transparent core;
(iii) forming a second transparent conductive layer on the opposite surface of the transparent core;
(iv) applying a UV-light sensitive composition (C1) on the first transparent conductive layer to form a first resist layer; and
(v) applying a visible-light sensitive composition (C2) on the second transparent conductive layer to form a second resist layer.

As mentioned previously, the first conductive layer 21 and the second transparent conductive layer 22 of the present transparent conductive substrate 100 (see FIG. 1) maybe formed by applying a dispersion containing the conductive material on one or both surfaces of the transparent core 10 by spin coating, dipping, or chemical vapor deposition (CVD).

To form the first resist layer 31 or second resist layer 32 may be done by coating the UV-light sensitive composition (C1) or the visible-light sensitive composition (C2) on the respective surface of the first transparent conductive layer 21 or the second transparent conductive layer 22 in a suitable solvent as described previously.

Alternatively, the first or second resist layer may be formed by laminating the set of dry films (i.e., DF1 and DF2) on the respective transparent conductive layer. If a cover sheet is present in the set of dry films, it may be removed, and the uncovered surface of the resist layer is laminated onto the pre-cleaned surface of the transparent conductive layer using heat and/or pressure, e.g., with a conventional hot-roll laminator. The laminating parameters including temperature, pressure, and duration may be appropriately selected as needed by one skilled in the art.

Noted that after laminating the DF1 and DF2, the resulting transparent conductive substrate comprises two additional polymeric films that are originated from the support films of the dry films DF1 and DF2. As shown in FIG. 2, the transparent conductive substrate 200 has a structure in sequence of: a first polymeric film 41, a first resist layer 31, a first transparent conductive layer 21, a transparent core 10, a second transparent conductive layer 22, a second resist layer 32, and a second polymeric film 42.

The polymeric films 41 and 42 act as protective sheets and the transparent conductive substrate 200 may be exposed to light rays through the polymeric films. In some instances, the polymeric films may be removed before irradiating to improve resolution and other such properties.

In one embodiment, the present transparent conductive substrate 200 is manufactured by a method comprising:
(I) providing a transparent core and a set of dry films consisting of a UV-light sensitive dry film (DF1) and a visible-light sensitive dry film (DF2);
(II) forming a first transparent conductive layer on one surface of the transparent core;
(III) forming a second transparent conductive layer on the opposite surface of the transparent core;
(IV) optionally, removing the first and the second protective films from the set of dry films if present; and
(V) laminating the UV-light sensitive dry film on the first transparent conductive layer and the visible-light sensitive dry film on the second transparent conductive layer simultaneously;
   wherein
the UV-light sensitive dry film (DF1) comprises a support film, a resist layer composed of a UV-light sensitive composition (C1), and optionally a protective film; and
the visible-light sensitive dry film (DF2) comprises a support film, a resist layer composed of a visible-light sensitive composition (C2), and optionally a protective film.

### Method for Manufacturing a Transparent Conductive Laminate

The present invention also provides a double-side photolithographic method for manufacturing a transparent conductive substrate, comprising:
(A) providing the transparent conductive substrate of the present invention;
(B) simultaneously exposing the first resist layer by a first light source and the second resist layer by a second light source;
(C) developing a first resist pattern and a second resist pattern simultaneously by removing the unexposed sections of the respective resist layers;
(D) etching portions of the first transparent conducive layer and the second transparent conductive layer that are unprotected by the respective resist patterns simultaneously; and
(E) stripping the first resist pattern and the second resist pattern simultaneously to provide a transparent conductive laminate;
   wherein
the transparent conductive laminate comprises a first conductive circuit and a second conductive circuit on each side of a transparent core, and the design patterns of the first conductive circuit and the second conductive circuit are different from each other;
the first light source and the second light source are positioned on the opposite side of the transparent conductive substrate;
the first light source irradiates light rays with a wavelength of below 400 nm and at a targeted exposure energy for the first resist layer, so that the second resist layer is substantially free from being patternized by the first light source;
the second light source irradiating light rays with a wavelength between 400 nm to 800 nm and at a targeted exposure energy to patternize the second resist layer, so that the first resist layer is substantially free from being patternized by light rays irradiated by the second light source.

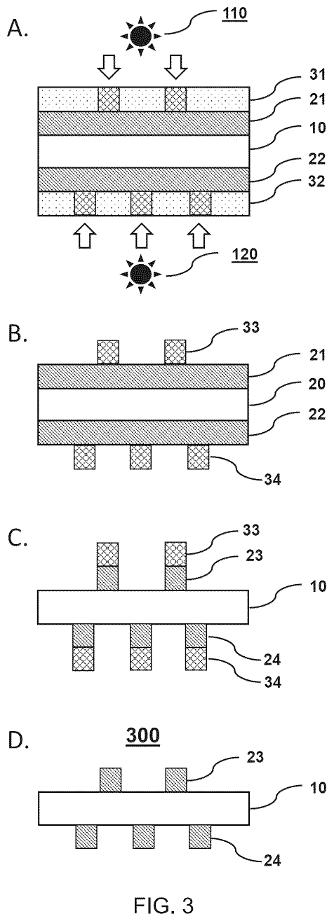

FIG. 3 shows each step of the present double-side photolithographic method for manufacturing a transparent conductive laminate.

The first step in the method of the invention is: (A) providing a transparent conductive substrate of the present invention that may be the transparent conductive substrate 100 as shown in FIG. 1 or the transparent conductive substrate 200 as shown in FIG. 2.

Referring to FIG. 3A, the present transparent conductive substrate is placed between two light sources that are positioned on the opposite side of the transparent conductive substrate so that the first resist layer 31 is facing the first light source 110, and the second resist layer 32 is facing the second light source 120.

The second step in the method of the invention is: (B) simultaneously exposing the first resist layer by a first light source and the second resist layer by a second light source (see FIG. 3A).

Examples of the exposure method include a method of irradiating light rays imagewise through a negative or positive pattern (i.e., a photomask), which is referred to as a mask exposure method. Alternatively, a method for irradiating light rays imagewise by a direct writing exposure method such as LDI (Laser Direct Imaging) exposure method or DLP (Digital Light Processing) exposure method may be used.

For example, for first resist layer that is UV-light sensitive photoresist, a LDI machine with 355 nm and 375 nm laser light may be selected; and for the second resist layer that is a visible-light sensitive photoresist, a LDI machine with 405 nm and 438 nm laser light may be selected.

Any convenient sources of active light rays providing wavelengths in the region of the spectrum that overlap the absorption bands of the photoinitiator and/or sensitizer may be used to activate the photopolymerization reactions. Conventional light sources include gas lasers such as a carbon arc lamp, a mercury vapor arc lamp, an ultra-high-pressure mercury lamp, a xenon lamp, or an argon laser; solid lasers such as a YAG laser; semiconductor lasers; ultraviolet rays such as a gallium nitride-based violet laser; and a lamp that efficiently emits visible light.

During the simultaneously exposing step (B), the first resist layer is irradiated by the first light source with UV light rays (below 400 nm) and the second resist layer by the second light source with visible-light rays (400 nm-800 nm). Since the transparent conductive substrate is “transparent”, there are incident light rays passed through the multilayer and reaches the resist layer on the opposite side.

One critical factor of the present method relies on the first resist layer and the second resist layer each has a different sensitivity for light rays of different wavelengths. Another critical factor is the capability of the dry film resist in blocking the active light rays of the specific resist layer to pass through and reach the resist layer situated on the opposite side of the transparent conductive substrate.

For example, the first resist layer 31 composed of the UV-light sensitive composition (C1) is photocured by exposing to UV-light rays with a wavelength of 400 nm or less, preferably, at 365 nm. Because the UV-light sensitive composition (C1) contains a UV-absorbing sensitizer (d1) and/or a visible-light blocking material (f), the first resist layer 31 is unreactive (or less sensitive) to the incident visible light rays used to expose the second resist layer. Similarly, the second resist layer is photocured by exposing to visible-light rays with a wavelength between 400 nm to 800 nm, and due to presence of a visible-light absorbing sensitizer (d2) and a UV-light blocking material (g) in the visible-light sensitive composition (C2), the second resist is unreactive to the incident light rays of <400 nm. Consequently, the present method may imagewise expose the first resist layer and the second resist layer simultaneously to form different or distinctive resist patterns on both sides of a transparent conductive substrate.

The third step in the method of the invention is: (C) developing a first resist pattern 33 and a second resist pattern 34 simultaneously by removing the unexposed sections of the respective resist layers (see FIG. 3B).

When the polymeric films remain on the first resist layer and the second resist layer, the support films are peeled off, and then the unexposed area of the respective resist layer are removed (developed). Examples of the development process include wet development and dry development, and the wet development is widely used.

The developing solution (i.e. developer) is generally an aqueous solution of from 0.01% by weight to 5% by weight of a water-soluble base. Suitable water-soluble bases include the alkali metal hydroxides such as lithium, sodium and potassium hydroxide; the base-reacting alkali metal salts of weak acids such as lithium, sodium and potassium carbonates and bicarbonates; ammonium hydroxide and tetra-substituted ammonium hydroxides such as tetramethyl and tetraphenyl ammonium hydroxide; sulfonium salts including the hydroxides, carbonates, bicarbonates, and sulfides; alkali metal phosphates and pyrophosphates such as sodium and potassium triphosphates and pyrophosphates; tetra-substituted phosphonium, arsonium, and stibonium hydroxides such as tetramethylphosphonium hydroxide. A preferred developer is a 0.1-3% by weight of sodium carbonate aqueous solution.

The developer may also contain surfactants. However, the total organic content should be less than 10% by weight, preferably less than 5% by weight.

The resist pattern development may be carried out on the first resist layer and the second resist layer simultaneously as a batch or a continuous process using any conventional technique, such as dipping or spraying. The development may be conducted at room temperature or heated to a temperature up to about 50° C. Many commercial processors are available for development.

The fourth step in the method of the invention is: (D) etching portions of the first transparent conducive layer and the second transparent conductive layer that are unprotected by the respective resist patterns (see FIG. 3C).

The etching method may be appropriately selected depending on the material constituted the transparent conductive layers to be removed. The etching method may be carried out on the first transparent conductive layer and the second transparent conductive layer simultaneously.

Examples of etching solutions include an solution for etching a silver-containing conductive layer, and the content of nitrate ions is about 16.0% by weight to about 35.0% by weight with respect to the total amount of the etching solution.

The ion source of nitrate ion is not particularly limited as long as it may be dissolved in water to generate nitrate ion. Examples of nitric acid ion sources include nitric acid, potassium nitrate, sodium nitrate, ammonium nitrate, uranyl nitrate, calcium nitrate, silver nitrate, iron(II) nitrate, iron(III) nitrate, and lead nitrate(II), barium nitrate, cobalt(II) nitrate, bismuth(III) nitrate, strontium nitrate, magnesium nitrate, calcium nitrate, diammonium cerium(IV) nitrate, palladium(II) nitrate, copper(II) nitrate, cadmium nitrate, tallium(III) nitrate, cerium(III) nitrate, zinc nitrate, nickel(II) nitrate, zirconyl nitrate, aluminum nitrate, lithium nitrate, mercury(II) nitrate, cesium nitrate, gadolinium(III) nitrate, erbium(III) nitrate, europium(III) nitrate, lutetium(III) nitrate, indium(III) nitrate, yttrium(III) nitrate, gallium nitrate, samarium(III) nitrate, or ytterbium(III) nitrate.

From the viewpoint of increasing the etching rate more easily, the ion source of nitrate ion preferably contains one or more selected from the group consisting of nitric acid, iron(II) nitrate and iron(III) nitrate. Iron(III) acts as an effective catalyst for nitric acid to oxidize silver in terms of redox potential. Therefore, from the viewpoint of increasing the etching rate more easily, the ion source of nitrate ion is more preferably containing iron(III) nitrate.

The fifth step in the method of the invention is: (E) stripping the first resist pattern and the second resist pattern simultaneously to provide a transparent conductive laminate having two conductive circuits 23 and 24 on both sides of the transparent core 10 (See FIG. 3D).

Once the first resist pattern and the second resist pattern have performed their function, the resist patterns may be then removed generally by an aqueous stripping solution that may contain organic amines or solvents to improve stripping speed or to minimize metal attack or staining. The aqueous stripping solution typically has stronger alkalinity than that of the aqueous developing solution used in developing the resist pattern. The aqueous stripping solution may be an aqueous solution of 1-10% by weight of sodium hydroxide or potassium hydroxide.

Examples of the resist pattern stripping methods include dipping and spraying, and these methods are used singly or in combination thereof. The stripping method may be carried out on the first transparent conductive layer and the second transparent conductive layer simultaneously.

Without further elaboration, it is believed that one skilled in the art using the preceding description may utilize the present invention to its fullest extent. The following examples are, therefore, to be construed as merely illustrative, and not limiting of the disclosure in any way whatsoever.

### EXAMPLES

### Materials

### Alkali-Soluble Copolymer (a):

A-1: a copolymer composed of methyl methacrylate/benzyl methacrylate/methacrylic acid/styrene (32/18/25/25), a Mw of 55,000, a dispersity of 2.2 and an acid value of 162.8 mg KOH/g.

### Polymerizable Compound (b)

B-1: polyethoxylated bis-phenol A dimethacrylate, total 17 EO, CAS #41637-38-1, purchased from Sartomer, trade name: BPE900.
B-2: trimethyolpropane trimethacrylate, CAS #3290-92-4, purchased from Sartomer, trade name: SR350NS.

### Photoinitiator (c)

C-1: o-Cl-HABI, 2-(2-chlorophenyl)-1-[2-(2-chlorophenyl)-4,5-diphenyl-2H-imidazol-2-yl]-4,5-diphenyl-1H-imidazole, CAS #7189-82-4, purchased from Hampford Research Inc.
C-2: TCDM-HABI, 2,2′,4-tris(2-chlorophenyl)-5-(3,4-dimethoxyphenyl)-4′,5′-diphenyl-1,1′-bi-1H-imidazole, CAS #100486-97-3, purchased from Hampford Research Inc.
C-3: OMNIRAD 369, 2-(dimethylamino)-1-[4-(4-morpholinyl)phenyl]-2-(phenylmethyl)-1-butanone, CAS #119313-12-1, purchased from IGM resins.
C-4: 3-cyclopentyl-1-[9-ethyl-6-(2-methylbenzoyl)-9H-carbazol-3-yl]-1-propanone-1-(O-acetyloxime), CAS #1227375-90-7, purchased from Changzhou Tronly New Electronic Materials Co., Ltd., product name: TR-PBG-304.

### Sensitizer (d)

D1-1: 4,4′-bis(diethylamino)benzophenone, CAS #90-93-7, purchased from Sigma-Aldrich.
D1-2: 4-(dimethylamino)benzophenone, CAS #530-44-9, purchased from Sigma-Aldrich.
D2-1: BFBK, 1,3-bis(1,3-dihydro-1,3,3-trimethyl-2H-indol-2-ylidene)-2-propanone, CAS #24293-93-4, purchased from Hampford Research Inc.
D2-2: 3-benzoyl-7-(diethylamino)-2H-benzipyran-2-one, CAS #77016-78-5, purchased from Changzhou Tronly New Electronic Materials Co., Ltd., product name: TR-PSS-202.

### Other Additives (e)

E-1: LCV, leuco crystal violet, CAS #603-48-5, purchased from Changzhou Tronly New Electronic Materials Co., Ltd., product name: TR-LCV.
E-2: 5-carboxy-1H-benzotriazole, CAS #60932-58-3, purchased from PMC Specialties Group USA.
E-3: 5-chloro-1H-benzotriazole, CAS #94-97-3, purchased from Sigma-Aldrich.
E-4: Malachite green, chloride salt, CAS #569-64-2, purchased from Sigma-Aldrich.
E-5: 4-tert-butylcatechol, CAS #98-29-3, purchased from Sigma-Aldrich.

### Visible-Light Blocking Material (f)

F-1: Eusorb UV-1995, peak absorption at 431 nm (0.2 weight % doped in PMMA polymer and coated to 25 μm film), purchased from Eutec Chemical Co., Ltd.

### UV-Light Blocking Material (g)

G-1: 2,2′,4,4′-tetrahydroxybenzophenone, CAS #131-55-5, peak absorption at 360 nm (0.2 weight % doped in PMMA polymer and coated to 25 μm film), purchased from Everlight Chemical, product name: Eversorb 51.

### Preparation of Dry Film Samples (M1-M11)

A photosensitive composition for forming a dry film sample was prepared by weighing each ingredient in parts by weight as listed in Table 1, then adding the ingredients to a solvent mixture of acetone and methanol (90:10, w/w) to form a coating solution having a solid content of about 3000. The coating solution was casted onto a polyethylene terephthalate (PET) film (i.e., a 16 μm thick support film, manufactured by Toray Industries, Inc.) and dried at room temperature to form a dry film sample containing a resist layer of about 15 μm in thickness on the PET film.

TABLE 1

| | Sample ID. | | | | | | | | | | |
|---|---|---|---|---|---|---|---|---|---|---|---|
| Ingredient | M1 | M2 | M3 | M4 | M5 | M6 | M7 | M8 | M9 | M10 | M11 |
| A-1 | 55 | 55 | 55 | 55 | 55 | 55 | 55 | 55 | 55 | 55 | 55 |
| B-1 | 30 | 30 | 30 | 30 | 30 | 30 | 30 | 30 | 30 | 30 | 30 |
| B-2 | 10 | 10 | 10 | 10 | 10 | 10 | 10 | 10 | 10 | 10 | 10 |
| C-1 | 3 | 3 | 3 | 3 | | | 3 | 3 | 3 | 3 | 3 |
| C-2 | | | | 2 | | | | | | | |
| C-3 | | | | | 2.2 | | | | | | |
| C-4 | | | | | | 2 | | | | | |
| D1-1 | 0.16 | | | | | | | | | | |
| D1-2 | | 0.25 | 0.5 | | | | 0.25 | | | | |
| D2-1 | | | | | | | | 0.15 | | 0.15 | 0.3 |
| D2-2 | | | | | | | | | 0.2 | | |
| E-1 | 0.3 | 0.3 | 0.3 | 0.3 | 0.3 | 0.3 | 0.3 | 0.3 | 0.3 | 0.3 | 0.3 |
| E-2 | 0.1 | 0.1 | 0.1 | 0.1 | 0.1 | 0.1 | 0.1 | 0.1 | 0.1 | 0.1 | 0.1 |
| E-3 | 0.1 | 0.1 | 0.1 | 0.1 | 0.1 | 0.1 | 0.1 | 0.1 | 0.1 | 0.1 | 0.1 |
| E-4 | 0.03 | 0.03 | 0.03 | 0.03 | 0.03 | 0.03 | 0.03 | 0.03 | 0.03 | 0.03 | 0.03 |
| E-5 | 0.05 | 0.05 | 0.05 | 0.05 | 0.05 | 0.05 | 0.05 | 0.05 | 0.05 | 0.05 | 0.05 |
| F-1 | | | | | | | 0.2 | | | | |
| G-1 | | | | | | | | | | 1.2 | 1.2 |

### Evaluation of Exposure Energy

A specimen containing each dry film sample M1-M11 was prepared to evaluate the exposure sensitivity. The specimen was prepared by laminating a dry film sample (M1-M11) to a PET film (16 μm thick, manufactured by Toray Industries, Inc.) at 120° C. using a hot roll laminator (HRL-24, DuPont Co., Wilmington, Del.) under a pressing pressure of 5 kg/cm² and a speed of 2 m/mmn, and then cooled to at room temperature for 1 hour to obtain a specimen for exposure energy evaluation. Each specimen was cut to a square piece (size: 15×15 cm²) having a structure of: PET film (i6 m)/Resist layer (15 μm)/PET film (i6 m).

Each specimen was irradiated by using a MA8 contact aligner (manufactured by SUSS MicroTech) equipped with a high-pressure mercury lamp and fitted with a photomask that was either a narrow band-pass filter for exposure in the range of 355-390 nm (UV light) or with a long-pass filter for exposure at >=400 nm (visible light). A step wedge (41 steps, manufactured by Stouffer) was then placed on the PET film, and irradiated with a pre-set exposure energy (e.g., 100, 150, up to 1000 mJ/cm²).

After the exposure and left at room temperature for more than 15 minutes, the PET film was peeled off. The specimen was developed by sprayed with a 1% sodium carbonate aqueous solution with a pressure of 0.2 MPa at 30° C. for a duration that was twice the developing time. After rinsing with deionized water and drying, the exposure energy resulting number of steps of held for the specimen as compared to a Stouffer 41 Step Wedge was recorded. The exposure energy (mJ) required to obtain a 12-steps held on a Stouffer 41 Step Wedge (E_{SST12}) for each of dry film resists were listed in Table 2. A larger exposure energy to yield the same number steps of held meant that the resist layer had a lower sensitivity at the selected exposure wavelength.

### Calculation of Trigger Energy

The exposure energy of each dry film sample to obtain a 0-step held on a Stouffer 41 Step Wedge (E_{SST0}) was reported as the trigger energy (E_{SST0}). The trigger energy may be calculated by the equation below:

E_{SST0}=E_{SST12}/4 (Equation 1)

The calculated E_{SST0} data of the dry film samples M1-M11 were listed in Table 2.

### Measurement of Dry Film Resists Transmittance

The transmittance of each dry film sample was measured using a Lambda 35-UV/VIS Spectrometer (manufactured by Perlin Elmer. Measurement conditions wavelength range: 200 nm to 800 nm, scanning speed: 300 nm/min, scanning interval: 0.50 nm). Baseline measurement was performed on the 16 μm thick PET film that was used as the support film of the dry film samples. The transmittance at 365 nm and 405 nm were recorded and listed in Table 2.

### Calculation of Incident Exposure Energy

As mentioned previously and referring to FIG. 3A, the present double-side photolithographic method uses two light sources that are positioned on the opposite side of the transparent conductive substrate. Assuming the first resist (DF1) is irradiated by the first light source with UV-light rays (e.g., at 365 nm) with an exposure energy of E_{SST12}, the exposure energy of the incident UV-light rays (Inc.E₃₆₅) may reach the second resist (DF2) is calculated by the transmittance at 365 nm (T₃₆₅) and the exposure energy (E_{SST12}) of DF1.

Similarly, for the second resist (DF2) is irradiated by the second light source with visible-light rays (e.g., at 405 nm) with an exposure energy of E_{SST12}, the exposure energy of the incident visible-light rays (Inc.E₄₀₅) may reach the first resist (DF1) is calculated by the transmittance at 405 nm (T₄₀₅) and the exposure energy (E_{SST12}) at 405 nm of DF2. The calculated exposure energy of the incident UV light rays (Inc.E₃₆₅) and the incident visible-light rays (Inc.E₄₀₅) of each dry film sample M1-M11 were listed in Table 2.

### Resolution Evaluation of Dry Film Samples M1-M11

The resolution of the dry film samples M1-M11 was evaluated on a laminate containing a specified dry film sample and a transparent conductive base. The transparent conductive base was composed of a PET film (i.e., the transparent core 10, size: 15 cm×15 cm×50 μm) and on each side of the PET film was coated with a thin layer of silver nanowire (i.e., the first and second transparent conductive layers 21 and 22). The dry film sample was placed on the transparent conductive base to obtain a perform.

The preform having a structure: [dry film sample/AgNW/PET/AgNW] was laminated at 120° C. using a hot roll laminator (HRL-24, DuPont Co., Wilmington, Del.) under a pressing pressure of 5 kg/cm² and a speed of 2 m/min, and then cooled to at room temperature for 15 minutes.

The resulting laminate was exposed with an exposure energy to obtain a 12-steps held on a Stouffer 41 Step Wedge (E_{SST12}) by a line mask (chrome glass mask) having a L/S ratio of the exposed portion to the unexposed portion being 1:1. The line width ranged from 5 m to 30 μm. The development was performed at a development time twice the minimum development time, and the minimum mask line width of the normally formed hardened photoresist line is taken as the resolution (in m), and was classified as follows:
⊚: the resolution is 10 μm or less.
◯: the resolution is between 10 μm and 15 μm.
×: the resolution is between 15 μm and 30 μm.

The resolution of each dry film sample was shown in Table 2.

TABLE 2

| Sample ID. | M1 | M2 | M3 | M4 | M5 | M6 | M7 | M8 | M9 | M10 | M11 |
|---|---|---|---|---|---|---|---|---|---|---|---|
| E_{SST12} at 365 nm | 155 | 185 | 146 | 64 | 155 | 9 | 234 | 260 | 292 | 558 | 392 |
| E_{SST0} at 365 nm | 39 | 46 | 37 | 16 | 39 | 2 | 59 | 65 | 73 | 140 | 98 |
| E_{SST12} at 405 nm | 592 | 1067 | 948 | 441 | 1006 | 2039 | 1131 | 468 | 468 | 526 | 310 |
| E_{SST0} at 405 nm | 148 | 267 | 237 | 110 | 252 | 510 | 283 | 117 | 117 | 132 | 78 |
| T % at 365 nm | 48 | 46 | 21 | 42 | 46 | 45 | 37 | 75 | 79 | 4 | 3 |
| T % at 405 nm | 81 | 93 | 87 | 86 | 93 | 94 | 35 | 44 | 49 | 43 | 20 |
| Inc. E₃₆₅ to DF2 | 74 | 85 | 31 | 27 | 71 | 4 | 87 | 195 | 231 | 22 | 12 |
| Inc. E₄₀₅ to DF1 | 480 | 992 | 825 | 379 | 936 | 1917 | 396 | 206 | 229 | 226 | 62 |
| Resolution at SST12 by UV light | ⊚ | ⊚ | ◯ | ⊚ | ⊚ | × | ⊚ | | | | |
| Resolution at SST12 by Visible | | | | | | | | ⊚ | ⊚ | ◯ | ◯ |
| light | | | | | | | | | | | |

### Preparation of Transparent Conductive Substrate of Example 1

Next, dry film samples M2 and M10 were placed on both sides of a transparent conductive base according to Table 3 as DF1 and DF2, respectively. The transparent conductive base was composed of a PET film (i.e., the transparent core 10, size: 15 cm×15 cm×50 μm) and on each side of the PET film was coated with a thin layer of silver nanowire (i.e., the first and second transparent conductive layers 21 and 22).

The stacked preform having a structure of PET/M2/AgNW/PET/AgNW/M10/PET was laminated at 120° C. using a hot roll laminator (HRL-24, DuPont Co., Wilmington, Del.) under a pressing pressure of 5 kg/cm² and a speed of 2 m/min, and then cooled to at room temperature for 1 hour to obtain a transparent conductive substrate of Example 1.

### Preparation of Transparent Conductive Substrate of Examples 2-8 and Comparative Examples 1-7

All working examples (E2-E8) and the comparative examples (CE1-CE7) were prepared by the same procedures as described above for Example 1. The set of dry film samples used in each working examples (E2-E8) and the comparative examples was listed in Table 3.

### Performance of the Working Examples (E1-E8) and the Comparative Examples (CE1-CE7)

The performance of transparent conductive substrate containing the set of designated DF1 and DF2 were evaluated after subjecting to the double-side photolithographic method. The prepared transparent conductive substrates of Examples 1-8 and CE1-CE7 having a structure of [PET/1^{st} Resist]/AgNW/PET/AgNW/[2^{nd} Resist/PET] were evaluated by being patternized by the incident light exposure.

The transparent conductive substrate was exposed by a line mask (chrome glass mask) having a L/S=15 μm/15 μm parallel line pattern. The first resist layer 31 was irradiated by a high-pressure mercury lamp and fitted with a photomask of horizontal line pattern for exposure in the range of 355-390 nm (UV light); the second resist layer 32 was irradiated by a high-pressure mercury lamp and fitted with a photomask of a vertical line pattern for exposure with visible-light rays at a wavelength >=400 nm.

After development, the patterns on both surfaces of the obtained transparent conductive laminate were visually checked by optical microscope. A pattern shape on one surface was reflected to the pattern shape on the other surface was evaluated and recorded in Table 3.

To avoid photocuring the DF2 by the incident UV light rays at 365 nm, suitable DF2 must have a trigger energy (E_{SST0}) at 365 nm that is at least higher than the incident exposure energy. To avoid photocuring the DF 1 by the incident visible-light rays at 405 nm, suitable DF1 must have a trigger energy (E_{SST0}) at 405 nm that is at least higher than the incident exposure energy (Inc.E₄₀₅). For example, if the dry film M3 is used as DF1, then potentially suitable dry film samples that be used as DF2 including M8-M11 according to Table 3.

The image performance of transparent conductive substrate was evaluated by the amount of residual resist left on the processed transparent conductive substrate after developing and recoded in Table 3.

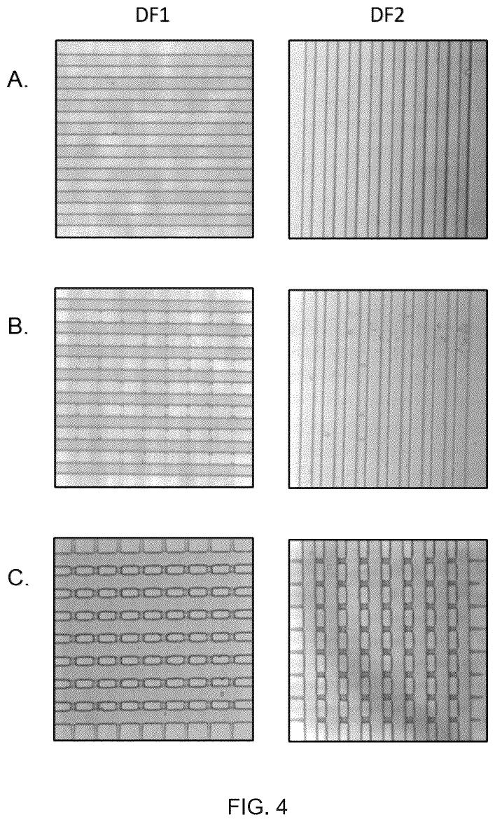

The image performance of transparent conductive substrate was categorized as follows:
⊚: the cross region between the horizontal lines and vertical lines showed no resist residue (see FIG. 4A)
◯: the cross region between the horizontal lines and vertical lines showed slight resist residue (see FIG. 4B)
×: the cross region between the horizontal lines and vertical lines showed significant resist pattern (see FIG. 4C)

TABLE 3

| Example | E1 | E2 | E3 | E4 | E5 | E6 | E7 | E8 | CE1 | CE2 | CE3 | CE4 | CE5 | CE6 | CE7 |
|---|---|---|---|---|---|---|---|---|---|---|---|---|---|---|---|
| first resist layer (DF1) | M2 | M3 | M4 | M5 | M6 | M5 | M7 | M7 | M1 | M8 | M8 | M8 | M1 | M1 | M1 |
| second resist layer (DF2) | M10 | M11 | M11 | M10 | M10 | M11 | M10 | M11 | M1 | M8 | M10 | M11 | M8 | M9 | M10 |
| Inc. E₄₀₅ from DF2 to DF1 | 226 | 62 | 62 | 226 | 226 | 62 | 226 | 62 | 480 | 206 | 226 | 62 | 206 | 229 | 226 |
| E_{SSTO} of DF1 at 405 nm | 267 | 237 | 110 | 252 | 510 | 252 | 283 | 283 | 148 | 117 | 117 | 117 | 148 | 148 | 148 |
| Image performance of DF1 | ◯ | ⊚ | ⊚ | ◯ | ⊚ | ⊚ | ◯ | ⊚ | × | × | × | ⊚ | × | × | × |
| Inc. E₃₆₅ from DF1 to DF2 | 85 | 31 | 27 | 71 | 4 | 71 | 87 | 87 | 74 | 195 | 195 | 195 | 74 | 74 | 74 |
| E_{SSTO} of DF2 at 365 nm | 140 | 98 | 98 | 140 | 140 | 98 | 140 | 98 | 39 | 65 | 140 | 98 | 65 | 73 | 140 |
| Image performance of DF2 | ◯ | ⊚ | ⊚ | ⊚ | ⊚ | ◯ | ⊚ | ◯ | × | × | × | × | × | × | ⊚ |

From the results listed in Table 3, the following are evident.

The transparent conductive substrates of Examples E1-E8, as compared with those of the comparative examples (CE 1-CE7), demonstrated good to excellent image performance that were evaluated by the resulting clear resist patterns on both sides of each transparent conductive substrate after stripping. In other words, there is no un-expected polymerization of the resist layers caused by the incident light rays from the opposite light source.

Due to the first resist layer and the second resist layer are photocured by light rays of different wavelength regions (i.e., UV-light rays or the visible-light rays), the suitable photosensitive compositions must have initiator(s) and/or sensitizer(s) that are designed to absorb either UV-light rays or visible-light rays. When a transparent conductive substrate having resist layers on both sides being the same, it is expected that by using the present double-side lithographic method, the resulting transparent conductive laminate will exhibit unacceptable image performance. The above statement is supported by the results found for CE1 and CE2.

Examining the data of CE1 in Table 3, the incident light energy from DF2 being dry film M1 to DF1 (Inc. E₄₀₅) is 480 mJ that is much higher than the trigger energy by visible light (E_{SST0} at 405 nm) of dry film M1 as DF1 (i.e., 148 mJ). In addition, the incident light energy from DF1 being dry film M1 to DF2 (Inc. E₃₆₅) is 74 mJ that is also higher than the trigger energy by UV light (E_{SST0} at 365 nm) of dry film M1 as DF2 (i.e., 39 mJ). Therefore, both of the first resist layer and the second resist layer were unavoidably patternized by the incident light rays transmitted through the transparent core from the opposite side.

Comparison between E1 (i.e., composed of dry films M2/M10) and CE7 (i.e., composed of dry films M1/M10), E1 used dry film M2 as the first resist layer, while CE7 used dry film M1 as the first resist layer. Both dry films M1 and M2 though each contains different sensitizer, they have similar E_{SST12} by UV light rays (155 mJ vs. 185 mJ). However, due to dry film M2 has a lower visible-light sensitivity than that of dry film M1 as judging by the respective trigger energy (E_{SST0} at 405 nm is 267 mJ for M2, 148 mJ for M1), the first resist layer composed of M2 in E1 was not patternized by the incident visible-light energy passed through the same second resist layer composed of dry film M10 (i.e., 226 mJ).

Comparison between E7 (M7/M10) and E1 (M2/M10), addition of a visible-light blocking material (f) in dry film M7, it apparently lowered the sensitivity of the incident visible light of M7, as judging by the E_{SST0} at 405 nm (283 mJ for M7 vs. 267 mJ for M2), and maintained similar resolution.

While the invention has been illustrated and described in typical embodiments, it is not intended to be limited to the details shown, since various modifications and substitutions are possible without departing from the spirit of the present invention. As such, modifications and equivalents of the invention herein disclosed may occur to persons skilled in the art using no more than routine experimentation, and all such modifications and equivalents are believed to be within the spirit and scope of the invention as defined by the following claims.

What is claimed is:

1. A transparent conductive substrate for manufacturing a transparent conductive laminate, sequentially comprising: a first resist layer, a first transparent conductive layer, a transparent core, a second transparent conductive layer, and a second resist layer;
wherein
the transparent conductive substrate has a total transmittance in the rage of 400 nm-800 nm (T₄₀₀₋₈₀₀) being 60% or more;
the first resist layer is composed of a UV-light sensitive composition;
the second resist layer is composed of a visible-light sensitive composition;
the UV-light sensitive composition undergoes photopolymerization by exposing to light rays with a wavelength of below 400 nm; and
the visible-light sensitive composition undergoes photopolymerization by exposing to light rays of a wavelength region of 400 nm to 800 nm.

2. The transparent conductive substrate of claim 1, wherein the UV-light sensitive composition comprises:
(a) 30-70% by weight of an alkali-soluble copolymer;
(b) 10-70% by weight of a polymerizable compound having an ethylenic unsaturated double bond;
(c) 0.1-20% by weight of a photoinitiator;
(d1) 0-20% by weight of a UV-absorbing sensitizer having maximum absorption in the UV-light region;
(e) 0-20% by weight of other additives; and
(f) 0-20% by weight of a visible-light blocking material by absorbing incident visible-light energy.

3. The transparent conductive substrate of claim 1, wherein the visible-light sensitive composition comprises:
(a) 30-70% by weight of an alkali-soluble copolymer;
(b) 10-70% by weight of a polymerizable compound having an ethylenic unsaturated double bond;
(c) 0.1-20% by weight of a photoinitiator;
(d2) 0.01-20% by weight of a visible-light absorbing sensitizer having a maximum absorption in the visible-light region;
(e) 0-20% by weight of other additives; and
(g) 0.01-20% by weight of a UV-light blocking material by absorbing incident UV-light energy.

4. The transparent conductive substrate of claim 1, wherein the transparent core is a sheet of glass, flexible glass, or quartz; or a polymeric film composed of polyethylene terephthalate, polybutylene terephthalate, polyethylene naphthalate, cellulose acetate, polyethylene, polypropylene, cyclic polyolefin, poly(meth)acrylate ester, polyacrylate, polyamide, polyimide, polycarbonate, poly(ether sulfone), polysulfone, or combinations thereof.

5. The transparent conductive substrate of claim 1, wherein each of the first transparent conductive layer and the second transparent conductive layer independently contains a conductive material selected from composed of indium tin oxide, indium zinc oxide, indium gallium zinc oxide; carbon nanotubes; and nanowires of copper, silver, platinum, or gold.

6. The transparent conductive substrate of claim 1, wherein the transparent core has a thickness of 1 μm to 200 μm; each of the first and the second transparent conductive layers independently has a thickness of 0.001 μm to 10 μm; and each of the first and the second resist layers independently has a thickness of 0.1 μm to 50 μm.

7. The transparent conductive substrate of claim 1, further comprising a first polymeric film contacting the first resist layer, and a second polymeric film contacting the second resist layer, wherein the first polymeric film and the second polymeric film each independently is composed of polyethylene terephthalate, polyethylene, or polypropylene; and each independently has a thickness of from 1 μm to 100 μm.

8. A method for manufacturing the transparent conductive substrate of claim 1, comprising:
(i) providing a transparent core;
(ii) forming a first transparent conductive layer on one surface of the transparent core;
(iii) forming a second transparent conductive layer on the opposite surface of the transparent core;
(iv) applying the UV-light sensitive composition (C1) of claim 2 on the first transparent conductive layer to form a first resist layer; and
(v) applying a visible-light sensitive composition (C2) of claim 3 on the second transparent conductive layer to form a second resist layer.

9. The method of claim 8, wherein step (ii) or step (iii) is independently conducted by spin coating, dipping, and chemical vapor deposition (CVD).

10. A set of dry films for manufacturing the transparent conductive substrate of claim 1, comprising: a UV-light sensitive dry film (DF1) and a visible-light sensitive dry film (DF2); wherein
the UV-light sensitive dry film (DF1) comprises a support film, a resist layer composed of the UV-light sensitive composition (C1) of claim 2, and optionally a protective film;
the visible-light sensitive dry film (DF2) comprises a support film, a resist layer composed of a visible-light sensitive composition (C2) of claim 3, and optionally a protective film;
each of the support film of the UV-light sensitive dry film (DF1) and the support film of the visible-light sensitive dry film (DF2) independently has a thickness of 1 μm to 100 μm; and
each of the protective film of the UV-light sensitive dry film (DF1) and the protective film of the visible-light sensitive dry film (DF2) independently has a thickness of 1 μm to 100 μm.

11. A method for manufacturing the transparent conductive substrate of claim 7, comprising:
(I) providing a transparent core and the set of dry films of claim 10;
(II) forming a first transparent conductive layer on one surface of the transparent core;
(III) forming a second transparent conductive layer on the opposite surface of the transparent core;
(IV) optionally, removing the first and the second protective films from the set of dry films if present; and
(V) laminating the UV-light sensitive dry film on the first transparent conductive layer and the visible-light sensitive dry film on the second transparent conductive layer simultaneously;

12. The method of claim 11, wherein step (II) or step (III) is independently conducted by spin coating, dipping and chemical vapor deposition (CVD).

13. A double-side photolithographic method for manufacturing a transparent conductive laminate, comprising:
(A) providing the transparent conductive substrate of claim 1 or claim 7;
(B) simultaneously exposing the first resist layer by a first light source and the second resist layer by a second light source;
(C) developing a first resist pattern and a second resist pattern simultaneously by removing the unexposed sections of the respective resist layers;
(D) etching the portions of the first transparent conducive layer and the second transparent conductive layer that are unprotected by the respective resist patterns simultaneously; and
(E) stripping the first resist pattern and the second resist pattern simultaneously to obtain a transparent conductive laminate;
wherein
the transparent conductive laminate comprises a first conductive circuit and a second conductive circuit on each side of a transparent core, and the design patterns of the first conductive circuit and the second conductive circuit are different from each other;
the first light source and the second light source are positioned on the opposite side of the transparent conductive substrate;
the first light source irradiates light rays with a wavelength of below 400 nm and at a targeted exposure energy for the first resist layer, so that the second resist layer is substantially free from being patternized by the first light source;
the second light source irradiating light rays with a wavelength between 400 nm to 700 nm and at a targeted exposure energy to patternize the second resist layer, so that the first resist layer is substantially free from being patternized by light rays irradiated by the second light source.

14. The double-side photolithographic method of claim 13, wherein the first light source irradiates light ray with a wavelength of 365 nm, and the second light source irradiates light ray with a wavelength of 405 nm or 438 nm.

15. A transparent conductive laminate, that is manufactured by the double-side photolithographic method of claim 13.

16. A touch panel, comprising the transparent conductive laminate of claim 15, wherein the touch panel is attached on an electronic display as an input device.

17. An article, comprising the touch panel of claim 16, wherein the article is an entertainment device, a mobile device, or an electronic device.
